(19) United States
(12) Patent Application Publication
(10) Pub. No.: US 2006/0199087 A1
(43) Pub. Date: Sep. 7, 2006

(54) Method of making an integrated circuit by modifying a design layout by accounting for a parameter that varies based on a location within an exposure field

(76) Inventors: Kevin D. Lucas, Meylan (FR); Robert E. Boone, Grenoble (FR); Kyle W. Patterson, Froges (FR)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/071,809

(22) Filed: Mar. 3, 2005

(51) Int. Cl. G03F 7/00

(52) U.S. Cl. 430/30; 430/311

(57) ABSTRACT

An original layout of an integrated circuit is modified using optical proximity correction (OPC) to obtain a second layout. During OPC, a sensitivity to flare for each feature is conveniently identified. To map the flare, the amplitude of intensity is mapped over a field of exposure, which is typically a rectangle-shaped area corresponding to an exposure of a stepper. The field of exposure is divided into regions in which a region is characterized as having substantially the same amplitude throughout. For each feature a decision is made whether to make a further correction or not. If correction is desired, the amount of correction is based in part on the region in which the feature is located and the sensitivity of the feature. This same approach is applicable to other properties than flare that vary based on the location within the field of exposure.

### FIELD OF THE INVENTION

This invention relates generally to integrated circuits, and more specifically, to forming integrated circuits by modifying the reticle design to compensate for a parameter which varies across an exposure field.

### BACKGROUND

When making an integrated circuit photolithography is used to transfer features from a reticle design to a semiconductor wafer. Since photolithography is typically not able to faithfully reproduce the reticle design on the wafer, the reticle design is adjusted so that the features on the semiconductor wafer are created at the desired dimensions. To determine and form the adjusted reticle design, the area around a feature on the reticle design must be considered. Procedures such as optical proximity correction (OPC) may be used. However, OPC typically only adjusts the reticle design by considering the local area of a certain feature. For example, OPC is typically run so that it considers the neighboring features within approximately a 1 micron diameter around a feature to be corrected.

Sometimes it is desirable to consider a wider area. For example, it may be desirable to adjust the reticle design based on a parameter that changes over the entire field of exposure but that is constant within a small area, such as the focus of the photolithography tool. To consider a wider area, the cycle time of the OPC measurements increases dramatically as the cycle time is generally a linear function of the area considered. This increase in cycle time is undesirable.

Therefore, a need exists to improve the cycle time for adjusting the reticle design when considering parameters that change over the entire field of exposure.

### BRIEF DESCRIPTION OF THE DRAWINGS

The present invention is illustrated by way of example and is not limited by the accompanying figures, in which like references indicate similar elements.

FIG. 1 illustrates a flow of an embodiment of the present invention;

FIG. 2 illustrates a result of mapping a variation of a property within a field of exposure in accordance with an embodiment of the present invention;

FIG. 3 illustrates an area of an integrated circuit design after performing an optical proximity correction (OPC) in accordance with an embodiment of the present invention;

FIG. 4 illustrates the area of FIG. 3 after calculating a sensitivity of the area to a property within a field of exposure in accordance with an embodiment of the present invention;

FIG. 5 illustrates the final reticle design for an area in accordance with an embodiment of the present invention;

FIG. 6 illustrates the final reticle design for another area in accordance with an embodiment of the present invention; and

FIG. 7 illustrates using a reticle (i.e., a mask) having the final reticle design to make an integrated circuit in accordance with an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

A method for forming an integrated circuit that is formed using a process that compensates for variation that occurs within an exposure field of a lithographic tool, but does not appear to be a variation on a small scale because the parameter is constant or varies almost negligibly in local areas (e.g., an area with a diameter of approximately 1 micron). The amplitude of the variation in the exposure field is stored. In addition the sensitivity of different device features to the variation may also be calculated and stored. The amplitude and the sensitivity measurements are combined to compensate for the variation by moving predetermined feature edges in a reticle layout database. In one embodiment, the compensation is performed after the application of model-based optical proximity correction (MBOPC). The method for compensating for the variation may in one embodiment be stored on a computer readable storage medium.

Thus, in one embodiment, a critical dimension (CD) altering effect is determined, the amplitude of the CD altering effect across a portion of the device layout is stored, the CD sensitivity of one of the layout features or layout feature edges to the CD altering effect is calculated, the layout features or layout feature edges are modified to compensate for the CD altering effect to develop a final or optimum layout, and the final layout is transferred to a semiconductor wafer using a reticle or direct write lithography. The modification of the layout features or layout feature edges may occur by using the amplitude of the CD altering effect and the CD sensitivity. In one embodiment, the modification involves the multiplication of the amplitude times the CD sensitivity.

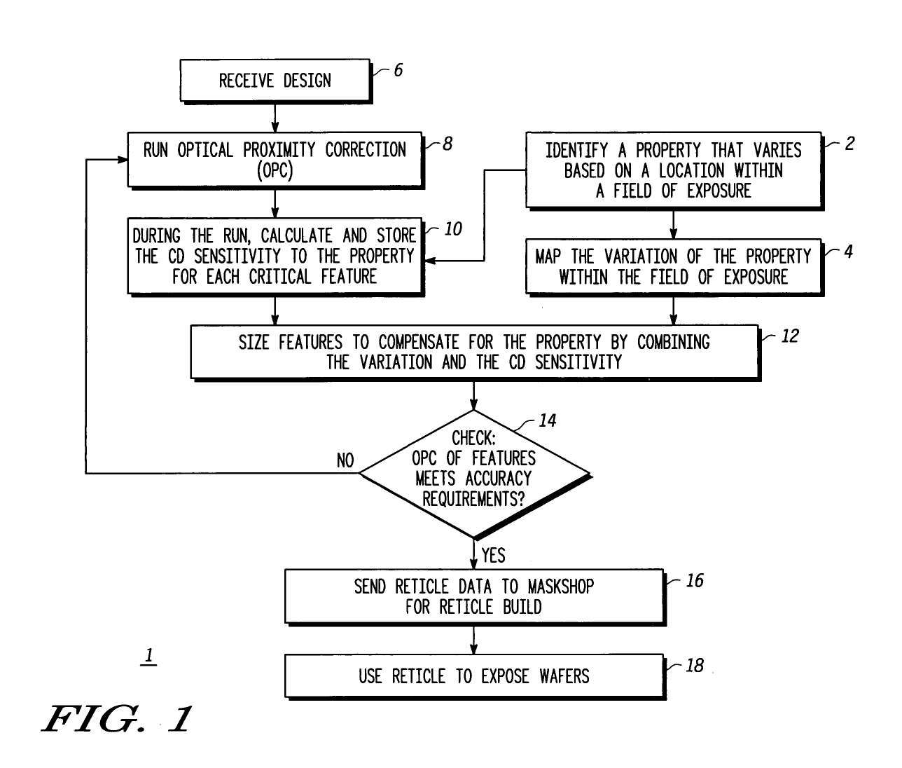

FIG. 1 illustrates a flow 1 used to form a portion of an integrated circuit. More specifically, the flow 1 is used to optimize a reticle design that is then used to expose a portion of a semiconductor wafer during an integrated circuit manufacturing process.

First, a property that varies based on a location within a field of exposure is identified 2. The property may be a field of focus, flare, dose, wafer topography, reticle phase, reticle transmission variations (such as reticle transmission intensity), lens aberrations, reticle topography, etch rate, light polarization, stepper illumination spatial distribution, stepper numerical aperture, substrate reflectivity, photoresist thickness, and wafer topography, the like, and combinations of the above. The property is likely to vary over a distance greater than the OPC distance, which is usually on the order of one micron, because otherwise the property would be considered and compensated for during an OPC process. Instead, the parameter varies over a distance that is greater than the distance that OPC examines around a feature. In one embodiment, the parameter varies over a distance that is greater than approximately 2 microns, or more specifically greater than approximately 10 microns. As will be better understood after further explanation, additional processing beyond OPC is needed to adjust for the parameter being identified and thus, the OPC process does not adjust for the parameter that varies based on a location within an exposure field.

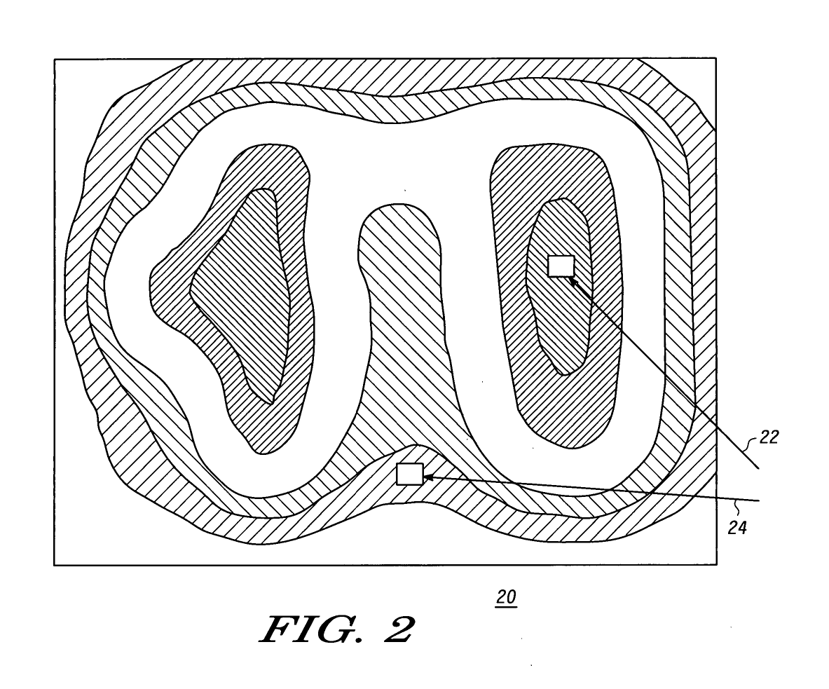

Once the property is identified 2, the variation of the property within the field of exposure is mapped 4. In one embodiment, the map is a topographic representation 20 that can be saved as a gds file, as shown in FIG. 2. The topographic representation 20 may be an amplitude or intensity of the variation. In some embodiments, the map may be a saved as a mathematical function or polygons on multiple design layers. The topographic representation 20 can be based on actual data from experiments or can be data from a model.

To form the topographic representation 20, in an embodiment where flare is the parameter that varies based on the location within the exposure field, many topographic representations are made resulting in a final topographic representation 20. A first topographic representation can be made in a spatial or frequency domain. In the spatial domain, the representation is similar to a contour map, however it shows the relative intensity difference compared to an average. A program capable of generating this type of representation is Calibre Hierarchical Design Verification software (also known as Calibre Hierarchical Design Rule Check software) made by Mentor Graphics® Corporation of Wilsonville, Oreg. A spatial representation can be converted to the frequency domain, and vice versa, using a Fourier transform function.

The first topographic representation is then defocused or blurred to form a second topographic representation. The defocusing or blurring can occur in many different ways. A simple way of defocusing is to obtain a color spatial map of the detailed topography and defocus your eyes. Another way to achieve lower resolution is to generate a transparency of the first representation and place it on an overhead projector. Make sure the image is out of focus to determine generally where the higher and lower points are. Another way to obtain the second topographic representation is to use a frequency domain representation of the first topographic representation and process it through a low pass filter. The low pass filter ignores the microscopic changes (high frequency changes in topography) but keeps the macroscopic changes (low frequency changes in topography).

A complementary image is then formed. The complementary image is the final topographic representation 20, which is in the spatial domain.

Illustrated in FIG. 2 are areas or cells 22 and 24. These cells have an identical feature layout but are located in different locations within the exposure field and have different values of the chosen parameter that varies based on the location within the exposure field. For example, cell 22 is located in an area that has more flare than cell 24. As will be understood after further explanation, because they are located in different locations within the exposure field and have different values of the chosen parameter, the final reticle designs for cells 22 and 24 are different. In contrast, if cells 22 and 24 were in areas of the exposure field where the values of the chosen parameter were identical the resulting design for both cells would be identical because the cells 22 and 24 have identical features layouts.

Either after, before, or performed in parallel to identifying the property 2 and mapping the variation 4, a design is received 6 and OPC is run 8. In other words, the sequence of identifying the property 2, mapping the variation 4, receiving the design 6 and running OPC 8 is immaterial except that the design needs to be received 6 prior to running OPC 8 and all four processes (identifying the property 2, mapping the variation 4, receiving the design 6, and running OPC 8) are performed prior to steps 10-18.

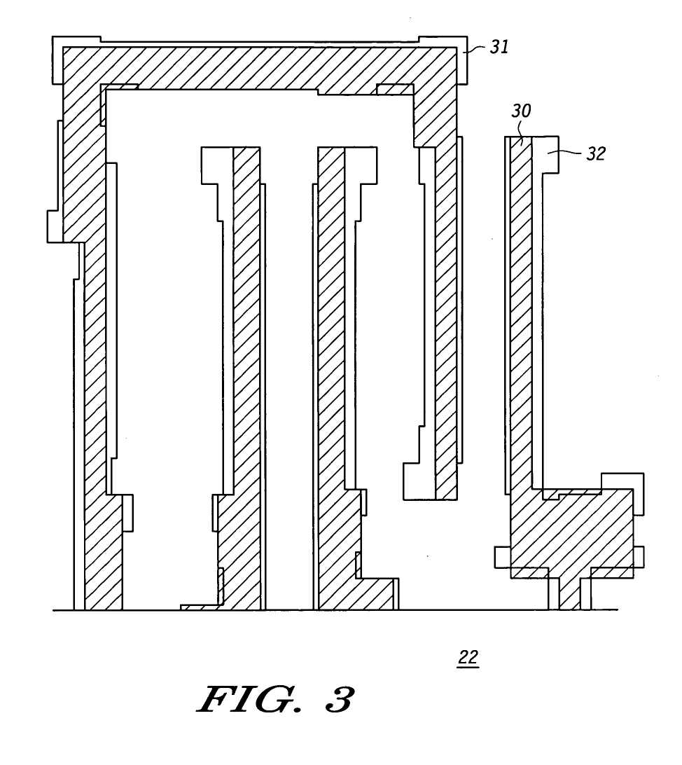

Receiving the design 6 can entail emailing to or loading the design onto a computer in one embodiment. After the design is received 6, OPC is run 8 on the design. OPC can be performed using a model based or rule based approach. In one embodiment, a model based approach (e.g., MBOPC) is used because it generates a resulting wafer pattern that matches the design 6 more than by the use of a rule based approach. In one embodiment, the Calibre Hierarchical Design Verification software can be used. This software will modify individual edges of a design to increase accuracy. Thus, a side of a feature having two corners may be divided into three segments: one segment for one corner, a second segment for the second corner, and a third segment between the first and second segments. For each segment, simulated intensity measurements are taken along a measurement line that intersects the segment. The number of measurements desired may depend on process or device parameters, such as the required wafer pattern accuracy. For example, if the accuracy requirements are not very tight fewer measurements may need to be taken and cycle time may be improved without degrading the quality of the results. The optical diameter used to make the measurements may be on the order of a micron with measurement spacing steps being a fraction of a micron in distance. The intensity measurements are used in an empirical function to predict edge patterning error on the wafer. If the error prediction at a specific spot is equal to or less than a predetermined threshold value, then no modification of the design is needed at that point. However, if the error prediction is greater than the threshold value then the design will be modified so that the design will print as originally desired. As a result of the modification, the predicted error value is reduced by moving polygon edges or adding polygons, such as a serif, to the features to meet or be below the threshold value at the point where the measurement value before modification was below the threshold value. For example, a serif 31, shown in FIG. 3, may be added to the first design to form a second design so that the feature will print as desired.

The second design, which is the original design modified by OPC, for the cell 22 or the equivalent cell 24 is shown in FIG. 3. The dashed portions 30 are the design features from the original design itself and the clear portions 32 are the portions added as a result of OPC. Since OPC does not consider the property that varies based on the exposure field in its analysis, the cells 22 and 24 do not differ at this point in the flow. In other words, because the cells 22 and 24 have identical original design layouts, after OPC and before further processing, the layout of the cells 22 and 24 are identical. Thus, FIG. 3 is a view of both the cell 22 and the cell 24 after OPC is performed.

While running OPC 8, critical dimension (CD) sensitivity of each feature or feature edge to the property that varies based on location within the exposure field is calculated and stored 10. Since the CD sensitivity is calculated and stored 10 while running OPC 8 the sensitivity measurement is a local measurement. Calculating and storing 10 the CD sensitivity can be conveniently done using the Calibre Hierarchical Design Verification software. However, any design rule checking (DRC) software, in one embodiment, can be used to determine sensitivity. To calculate the CD sensitivity an intensity gradient calculation may be performed over the measurement points for each of the measurement lines during OPC. The sensitivity is a measure of how much change in the design is required to compensate for a certain amount of change in the parameter. The sensitivity measurement is thus the slope of a line, equal to dy/dx, on a graph with the parameter variation on the y-axis and the reticle design CD on the x-axis. The greater the slope the more sensitive the feature. For example if flare is the parameter, an isolated feature is likely to have a low slope because it is not very sensitive to flare; only a small change in the edges of the isolated feature is required to compensate for a large flare variation. Other definitions of sensitivity such as the inverse slope, dx/dy, in the graph could also be used. Sensitivity may also be estimated using rule based OPC or DRC methods or by comparing the simulated intensity results from using different OPC input parameter values such as lens aberrations or wafer CD target. CD sensitivity is strongly influenced by any closely surrounding features of an area, as for example within an OPC simulation region.

The sensitivity calculations can be a calculation of feature edges or features sensitivities that occurs during OPC. To improve cycle time the calculation of sensitivity may occur only on critical regions, such as a minimum CD of a gate electrode, whether or not the calculation is done during OPC. (Gate electrode dimensions are often critical as the width of the gate electrode is an important feature for the reliability and functioning of a transistor.)

The sensitivity calculation can be stored in many ways. For example, if using the Calibre Hierarchical Design Verification software, the calculation can be saved electronically using this software. The storage format may include storing the data as multiple layers, tags, edge properties, sub-edge properties, feature properties, text, labels, cell names, the like, and combinations of the above.

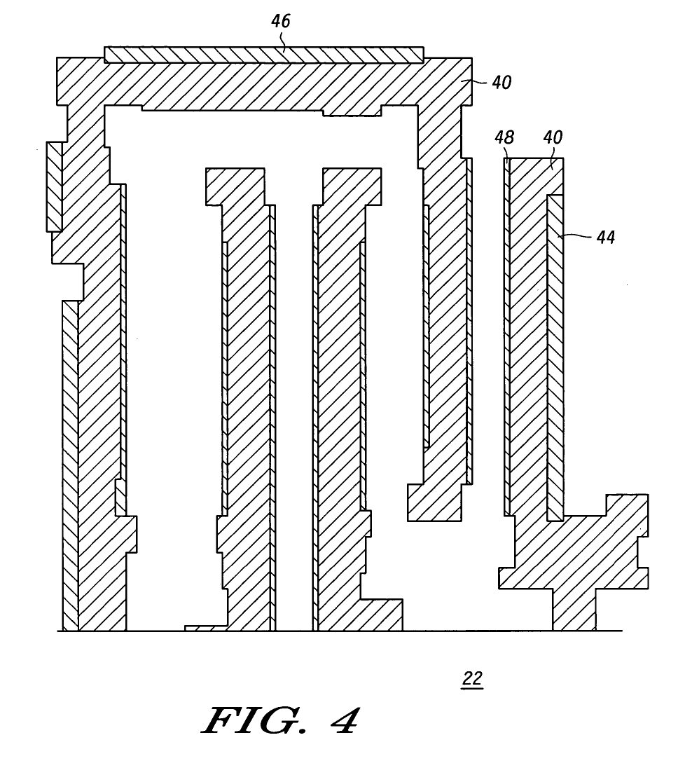

FIG. 4 illustrates one embodiment of the cell 22 after sensitivity has been calculated and stored as at least one layer of a file for the reticle. Area 40 is the features as obtained after OPC. The areas 44, 46, and 48 are the storage features for sensitivity. The areas 44, 46, and 48 are different widths, meaning that these areas have different sensitivities. For example, the area 48 is less sensitive than area 46, which is wider. Likewise, the area 46 is equally as sensitive as area 44. As with FIG. 3, FIG. 4 is also an illustration of the cell 24 because the variation of the property within the field of exposure, which differs for the cells 22 and 24, has not been taken into account yet.

After calculating and storing the CD sensitivity 10, the features may be sized 12 to compensate for the chosen property that varies based on a location within the exposure field by combining the variation data with the CD sensitivity. Therefore, in one embodiment, the sizing occurs after OPC is completed. Combining the variation data with the CD sensitivity can occur in many ways. In one embodiment, rules or a look-up table, such as a matrix, are used to determine the modifications to the layout. For example, a matrix of CD sensitivity and the variation can be created. The values that are entered in the matrix for a given sensitivity and a given variation may be determined empirically from a test structure or another experiment or simulated. Using such a matrix may also be referred to as binning. In other embodiments, the variation and the CD sensitivity can be combined by multiplication or convolving them together. In one embodiment, the Calibre Hierarchical Design Verification software or any design rule checking (DRC) software may be used to size the features by taking the chosen property into consideration. The greater the parameter variation amplitude and the higher the sensitivity, the greater the correction which will be made. Regardless, the correction may be optimized or limited to avoid the corrections affecting other features. The knowledge of which corrections to optimize or limit may occur from experimental or simulation data. In addition, the sizing of the features may occur preferentially on one edge (i.e., either the left or right side) of a gate electrode to increase feature correction accuracy, in one embodiment. Thus, the modifications in the layout may only be performed on critical regions, such as portions of or only certain minimum CD regions of a gate electrode.

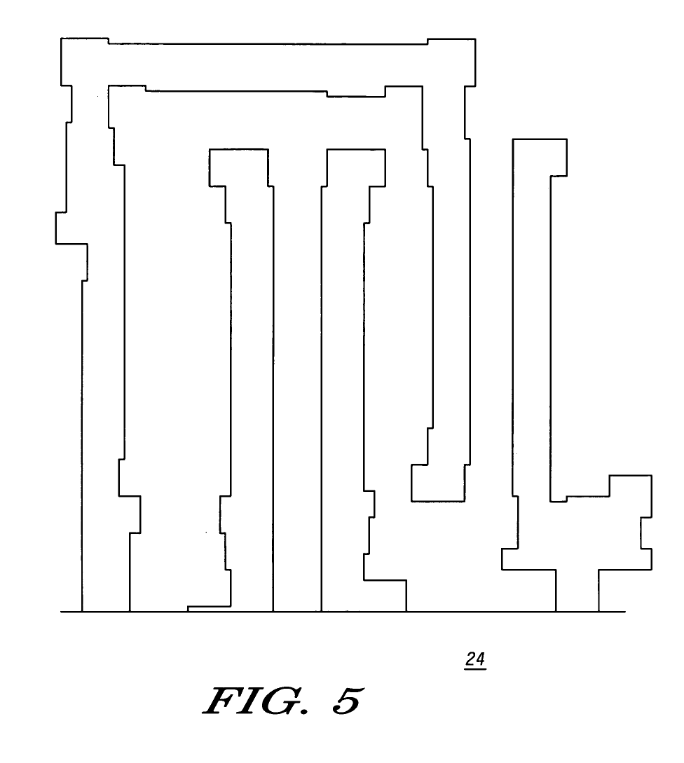

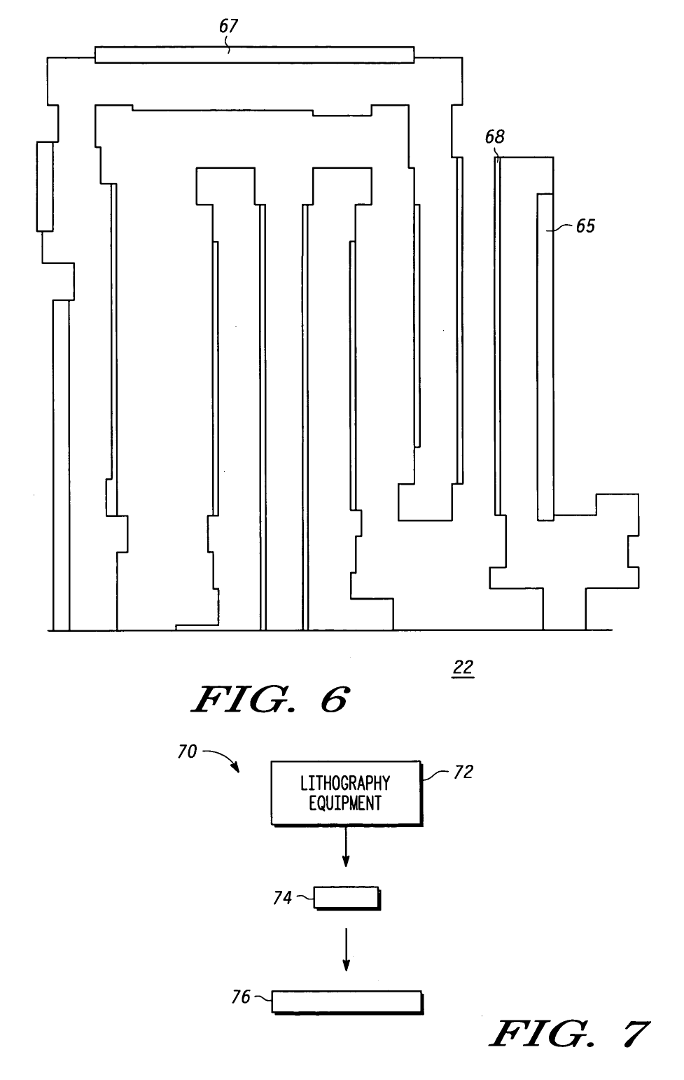

The combination of the variation and the CD sensitivity is then applied to the design modified by OPC so that the design is further modified resulting in the third or final design. As shown in FIG. 5, due to the location of the cell 24 within the exposed region, no modifications are needed to the second design. Thus, the final design for the cell 24 is the same as the second design. In contrast, as shown in FIG. 6, to form the final design for the cell 22, the second design needs to be modified by adding or modifying features 65, 67, and 68 because of the cell's 22 sensitivity and location within the exposure field. FIGS. 5 and 6 show how two cells (22 and 24) that are identical except for their location within the exposure field may have different final designs based on also considering the chosen parameter that varies within the exposure field.

Using the final design of all cells, a check is performed 14 to determine if the features in the second design meet the accuracy requirements. If not, the OPC is re-run, the calculation and storage of the CD sensitivity is performed again, and the features are re-sized to compensate for the chosen property that varies based on location within a field of exposure. In other words, steps 8, 10, and 12 are repeated. In one embodiment, only certain regions of the layout are re-run because these regions only did not meet the accuracy requirements. For example, if errors are found in one area of the layout, only this area may be re-run to improve cycle time.

Once the check 14 is passed, in one embodiment the reticle date for the final design is sent 16 to the mask shop for a reticle to be built (i.e., manufactured) using processes known in the art by a skilled artisan. After the reticle is manufactured, the reticle is used 18 to expose a semiconductor wafer and manufacture integrated circuits. As shown in FIG. 7, the reticle 74 can be used with the lithography equipment 72 to expose a semiconductor wafer 76. The semiconductor wafer 76 can be any semiconductor material and can be at any stage of processing where photolithography may be used. Thus, the semiconductor wafer 76 may have transistors or parts of transistors formed thereon. In one embodiment, a direct write lithographic process using the final design is used to form a semiconductor device.

By now it should be appreciated that there has been provided a method for taking into account a chosen property or parameter that varies based on a location within an exposure field without dramatically increasing cycle time. In addition, this method minimizes the amount of computer internal memory needed to form a final design taking the property into consideration. Taking into account the parameters that change based on the location within an exposure field can allow one to optimize corrections for such parameters to improve die to die reticle inspection, G-copy defect repair, and the like. In addition, this process can allow one to optimize the OPC process knowing that the correction for parameters that change based on the location within an exposure field will occur later in the process. For example, fragmentation, lower parameter sensitivity, lower OPC simulation diameter, the like, and combination of the above can be implemented in the OPC process to improve optimization of such process without adversely affecting the layout for the parameters that change based on the location within the exposure field. In addition, the measurement of mask error enhancement factor (MEEF) can be used with the CD sensitivity to help determine optimum feature or edge correction.

In the foregoing specification, the invention has been described with reference to specific embodiments. However, one of ordinary skill in the art appreciates that various modifications and changes can be made without departing from the scope of the present invention as set forth in the claims below. For example, more than one property that varies based on a location within the field of exposure can be considered. In such an embodiment, the combining of the variation and the sensitivities for each parameter can be done in series or simultaneously.

In one embodiment, a method for making an integrated circuit includes providing a first layout of the integrated circuit comprising a plurality of types of features, performing optical proximity correction on the first layout that changes the plurality of types of features in order to obtain a second layout of the integrated circuit, identifying a field of exposure, identifying a property that varies based on a location within the field of exposure, mapping an amplitude of the property in the field of exposure, identifying a plurality of regions in the field of exposure, wherein each region of the plurality of regions defines an area in the second layout in which the amplitude of the property is substantially the same, changing the features of the plurality of types of features in the second layout based on the region in which the features reside and a sensitivity to the property of the features to provide a third layout wherein the sensitivity to the property is measured for each of the features during the performing the optical proximity correction, and using the third layout to define patterns on a semiconductor wafer, wherein the integrated circuit is located on the semiconductor wafer. In one embodiment, the property is at least one of flare, dose, focus, lens aberrations, reticle phase, reticle transmission intensity, reticle topography, etch rate, light polarization, stepper illumination spatial distribution, stepper numerical aperture, substrate reflectivity, photoresist thickness and wafer topography. In one embodiment, the sensitivity incorporates mask error enhancement factor (MEEF). In one embodiment, the property that varies based on a location within the field of exposure varies over a range greater than ten microns. In one embodiment, the identifying a plurality of regions in the field of exposure further includes storing the plurality of regions on at least one design layer. In one embodiment, the using the third layout includes making a mask from the third layout, and using the mask to expose the semiconductor wafer. In one embodiment, the changing the features includes using at least one of a list, a table, design rule check functions, a mathematical function, a Boolean operation, a model-based optical proximity correction edge movement, an edge sizing operation, and a feature sizing operation. In one embodiment, the plurality of the types of features includes at least one of gates, end of lines, feature corners, and sides of lines. In one embodiment, the sensitivity to the property is stored using at least one of multiple design layers, feature tags, edge tags, edge properties, sub-edge properties, feature properties, text, labels, and cell names. In one embodiment, the providing a third layout further includes optimizing the third layout to allow improved at least one of die-die reticle inspection, and G-copy defect repair. In one embodiment, the changing of features of the plurality of types of features in the second layout further includes a second optical proximity correction step on at least one of the features.

In one embodiment, a method for making an integrated circuit including providing a first layout of the integrated circuit, performing optical proximity correction on the first layout to obtain a second layout of the integrated circuit, identifying a field of exposure, identifying a property that varies based on a location within the field of exposure, mapping an amplitude of the property in the field of exposure, identifying a plurality of regions in the field of exposure, wherein each region of the plurality of regions defines an area in the second layout in which the amplitude of the property is substantially the same, changing features of the second layout based on the region in which the features reside and sensitivities to the property to provide a third layout, and using the third layout to define patterns on a semiconductor wafer, wherein the integrated circuit is located on the semiconductor wafer. In one embodiment, the property is at least one of flare, dose, focus, lens aberrations, reticle phase, reticle transmission intensity, reticle topography, etch rate, light polarization, stepper illumination spatial distribution, stepper numerical aperture, substrate reflectivity, photoresist thickness and wafer topography. In one embodiment, the sensitivities incorporate mask error enhancement factor (MEEF). In one embodiment, the property that varies based on a location within the field of exposure varies over a range greater than ten microns. In one embodiment, the identifying a plurality of regions in the field of exposure further includes storing the plurality of regions on at least one design layer. In one embodiment, the using the third layout includes making a mask from the third layout, and using the mask to expose the semiconductor wafer. In one embodiment, the changing the features includes using at least one of a list, a table, design rule check functions, a mathematical function, a Boolean operation, a model-based optical proximity correction edge movement, an edge sizing operation, and a feature sizing operation. In one embodiment, the CHANGING features further includes changing at least one of a gate, an end of line, a feature corner, and a side of a line. In one embodiment, the sensitivities to the property are stored using at least one of multiple design layers, feature tags, edge tags, edge properties, sub-edge properties, feature properties, text, labels, and cell names. In one embodiment, the providing a third layout further includes optimizing the third layout to allow improved at least one of die-die reticle inspection, and G-copy defect repair. In one embodiment, the changing of features in the second layout further includes a second optical proximity correction step on at least one of the features.

In one embodiment, a method for making an integrated circuit includes providing a first layout of the integrated circuit comprising a plurality of types of features, identifying a field of exposure, identifying a property that varies based on a location within the field of exposure, determining an amplitude of the property in the field of exposure, changing the features of the plurality of types of features in the first layout based on the amplitude of the property and a sensitivity to the property of the features to provide a second layout, and using the second layout to define patterns on a semiconductor wafer, wherein the integrated circuit is located on the semiconductor wafer.

Accordingly, the specification and figures are to be regarded in an illustrative rather than a restrictive sense, and all such modifications are intended to be included within the scope of the present invention. Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,”, “have,” “having,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one.

1. A method for making an integrated circuit, comprising:
providing a first layout of the integrated circuit comprising a plurality of types of features;
performing optical proximity correction on the first layout that changes the plurality of types of features in order to obtain a second layout of the integrated circuit;
identifying a field of exposure;
identifying a property that varies based on a location within the field of exposure;
mapping an amplitude of the property in the field of exposure;
identifying a plurality of regions in the field of exposure, wherein each region of the plurality of regions defines an area in the second layout in which the amplitude of the property is substantially the same;
changing the features of the plurality of types of features in the second layout based on the region in which the features reside and a sensitivity to the property of the features to provide a third layout wherein the sensitivity to the property is measured for each of the features during the performing the optical proximity correction; and
using the third layout to define patterns on a semiconductor wafer, wherein the integrated circuit is located on the semiconductor wafer.

2. The method of claim 1, wherein the property is at least one of flare, dose, focus, lens aberrations, reticle phase, reticle transmission intensity, reticle topography, etch rate, light polarization, stepper illumination spatial distribution, stepper numerical aperture, substrate reflectivity, photoresist thickness and wafer topography.

3. The method of claim 1, wherein the sensitivity incorporates mask error enhancement factor (MEEF).

4. The method of claim 1, wherein the property that varies based on a location within the field of exposure varies over a range greater than ten microns.

5. The method of claim 1, wherein the identifying a plurality of regions in the field of exposure further includes storing the plurality of regions on at least one design layer.

6. The method of claim 1, wherein the using the third layout comprises:
making a mask from the third layout; and
using the mask to expose the semiconductor wafer.

7. The method of claim 1, wherein the changing the features includes using at least one of a list, a table, design rule check functions, a mathematical function, a Boolean operation, a model-based optical proximity correction edge movement, an edge sizing operation, and a feature sizing operation.

8. The method of claim 1, wherein the plurality of the types of features comprise at least one of gates, end of lines, feature corners, and sides of lines.

9. The method of claim 1, wherein the sensitivity to the property is stored using at least one of multiple design layers, feature tags, edge tags, edge properties, sub-edge properties, feature properties, text, labels, and cell names.

10. The method of claim 1, wherein the providing a third layout further includes optimizing the third layout to allow improved at least one of die-die reticle inspection, and G-copy defect repair.

11. The method of claim 1, wherein the changing of features of the plurality of types of features in the second layout further includes a second optical proximity correction step on at least one of the features.

12. A method for making an integrated circuit, comprising:
providing a first layout of the integrated circuit;
performing optical proximity correction on the first layout to obtain a second layout of the integrated circuit;
identifying a field of exposure;
identifying a property that varies based on a location within the field of exposure;
mapping an amplitude of the property in the field of exposure;
identifying a plurality of regions in the field of exposure, wherein each region of the plurality of regions defines an area in the second layout in which the amplitude of the property is substantially the same;
changing features of the second layout based on the region in which the features reside and sensitivities to the property to provide a third layout; and
using the third layout to define patterns on a semiconductor wafer, wherein the integrated circuit is located on the semiconductor wafer.

13. The method of claim 12, wherein the property is at least one of flare, dose, focus, lens aberrations, reticle phase, reticle transmission intensity, reticle topography, etch rate, light polarization, stepper illumination spatial distribution, stepper numerical aperture, substrate reflectivity, photoresist thickness and wafer topography.

14. The method of claim 12, wherein the sensitivities incorporate mask error enhancement factor (MEEF).

15. The method of claim 12, wherein the using the third layout comprises:
making a mask from the third layout; and
using the mask to expose the semiconductor wafer.

16. The method of claim 12, wherein the changing features further comprises changing at least one of a gate, an end of line, a feature corner, and a side of a line.

17. The method of claim 12, wherein the sensitivities to the property are stored using at least one of multiple design layers, feature tags, edge tags, edge properties, sub-edge properties, feature properties, text, labels, and cell names.

18. The method of claim 12, wherein the providing a third layout further includes optimizing the third layout to allow improved at least one of die-die reticle inspection, and G-copy defect repair.

19. The method of claim 12, wherein the changing of features in the second layout further includes a second optical proximity correction step on at least one of the features.

20. A method for making an integrated circuit, comprising:
providing a first layout of the integrated circuit comprising a plurality of types of features;
identifying a field of exposure;
identifying a property that varies based on a location within the field of exposure;
determining an amplitude of the property in the field of exposure;
changing the features of the plurality of types of features in the first layout based on the amplitude of the property and a sensitivity to the property of the features to provide a second layout; and
using the second layout to define patterns on a semiconductor wafer, wherein the integrated circuit is located on the semiconductor wafer.
